(19) United States
(12) Patent Application Publication
(10) Pub. No.: US 2013/0109198 A1
(43) Pub. Date: May 2, 2013

(54) HIGH CARBON CONTENT MOLECULES FOR AMORPHOUS CARBON DEPOSITION

(71) Applicants: Christian DUSSARRAT, Wilmington, DE (US); Vincent M. OMARJEE, Grenoble (FR)

(72) Inventors: Christian DUSSARRAT, Wilmington, DE (US); Vincent M. OMARJEE, Grenoble (FR)

(73) Assignee: AMERICAN AIR LIQUIDE, INC., Fremont, CA (US)

(21) Appl. No.: 13/281,620

(22) Filed: Oct. 26, 2011

(51) Int. Cl. H01L 21/31

(52) U.S. Cl. 438/778; 257/E21.24

(57) ABSTRACT

The disclosure relates to a method of depositing amorphous carbon on a substrate using at least one carbon containing molecule having at least one carbon atom the method comprising the steps of supplying the carbon containing molecule and carrying out the deposition to thereby form a deposited amorphous carbon on the substrate, wherein a carbon to hydrogen ratio of the molecule is equal to or more than 0.7.

### BACKGROUND

Carbon and generally amorphous Carbon (a-C) films are used in a variety of semiconductor application. Amorphous Carbon films are for instance used as hardmask material. With introduction of new low-k materials (often porous), film strength drastically decreased and damages (such as deformation) appeared during the various processes steps (chemical mechanical polishing—CMP for instance). Using a-C as hardmask helps preventing those damages on the low-k materials. Other use of hardmask is also as etch mask where it protects the underneath material during the etching steps.

Amorphous carbon material (also called amorphous hydrogenated carbon, a-C, a-C:H) is a widely used material as hardmask for metals, amorphous silicon and dielectric materials (SiO₂, SiN . . . ). It is considered that a-C has no long-range crystalline order; a-C is chemically inert, transparent and has very good mechanical properties. Typically, a-C films are deposited using plasma enhanced chemical vapor deposition with a tuned hydrogen ratio (from 10 to 45%).

### STATE OF THE ART

With the constant miniaturization of the feature sizes of IC circuits, the etching step is becoming more and more challenging. The depth of focus of the lithography also decreases that result in use of thinner masks. When the mask thickness is becoming too small, it starts to be softer and it does not play his role anymore: we have a loss of critical dimension (CD). To solve this issue, new etch resistant hard mask are required. Amorphous carbon layers are commonly used as hard mask material in Reactive Ion Etching (RIE) processes. One important criteria for the etch resistivity will be the Carbon to Hydrogen ratio.

The hardmask can also act as a protecting layer for the sidewall. When the hardmask is etched using S-containing molecule for instance, a passivation layer is formed on the sidewall by reaction of the Carbon etched and the Sulfur generated. (US2009047789A- Hynix)

Very recently, Lee et al (US20100093187) described the use of molecules having a carbon to hydrogen ratio of 2:3 or 1:2 or greater (for instance: acetylene, vinylacetylene, benzene, styrene, toluene, xylene, pyridine, acetophenone, phenol, furan, C₃H₂, C₅H₄, monofluorobenzenes, difluorobenzenes, tetrafluorobenzenes, and hexafluorobenzene(s) at low pressure (2-20 Torr) and a temperature range of 300-480° C.

### SUMMARY OF THE INVENTION

The present invention is related to a method of manufacturing semiconductor devices in which the amorphous carbon is deposited using very high carbon content molecules that are volatiles and reactive. Having a volatile molecule is critical for the facilitization of the proposed solution.

The invention may be summarized in part by the following sentences:
A method of depositing amorphous carbon on a substrate using at least one carbon containing molecule having at least one carbon atom the method comprising the steps of supplying the carbon containing molecule and carrying out the deposition to thereby form a deposited amorphous carbon on the substrate, wherein a carbon to hydrogen ratio of the molecule is equal to or more than 0.7.
The method of paragraph [0008] wherein the carbon to hydrogen ratio of the carbon containing molecule is equal to or more than 1.
The method of paragraph [0008] or [0009], wherein the carbon containing molecule is represented by the general formula CxHy with x and y being an integer >0.
The method of paragraph [00010], wherein x/y ratio is >0.7.
The method of paragraph [00010], wherein the ratio x/y≧1.
The method of any one of paragraphs [0008]-[00012] or any combinations of two or more of paragraphs [0008]-[00012], wherein the amorphous carbon deposition step comprises chemical vapor deposition (CVD), plasma enhanced-CVD (PECVD), pulsed-CVD, pulsed-PECVD, atomic layer deposition (ALD), plasma enhanced ALD (PEALD), cat-CVD, sub atmospheric CVD (SACVD), or a derivate method.
The method of any one of paragraphs [0008]-[00013] or any combinations of two or more of paragraphs [0008]-[00013], wherein the method further comprises a step of co-implanting the amorphous carbon with other elements.
The method of any one of paragraphs [0008]-[00014] or any combinations of two or more of paragraphs [0008]-[00014], wherein the carbon containing molecule is one or more of: C₆F₆, diphenylacetylene, naphthalene, azulene, cyclooctatetraene, Norbadiene, cycloheptatriene, cyclohexadiene, cyclopentadiene, diethynylbenzene, phenylacetylene, phenylpropyne, ethynyltoluene, hexadiyne, phenyl butyne, 1,5-hetadiyne, (tButyl)phenylacetylene, methylbutenyne, cyclopropylacetylene, ethynylcyclohexene, cyclopentylacetylene, or methylbutyne.
The method of any one of paragraphs [0008]-[00015] or any combinations of two or more of paragraphs [0008]-[00015], wherein the deposition step comprises is a plasma induced reaction that yields reaction products of the carbon containing molecule.
The method of any one of paragraphs [0008]-[00016] or any combinations of two or more of paragraphs [0008]-[00016], wherein the deposition step comprises a step of supplying an inert or a reactive gas in addition to the carbon containing molecule.
The method of paragraph [00017], wherein the inert or reactive gas is one or more of N₂, H₂, NH₃, O₂, CO₂, CO, benzene, CH₄, pentadiene, hexadiene, cyclohexylacetylene, C₂H₂, or C₂H₄.
The method of any one of paragraphs [0008]-[00018] or any combinations of two or more of paragraphs [0008]-[00018], wherein the deposited amorphous carbon is deposited on patterned structures with a conformality of at least 50%.
The method of paragraph [00019], wherein the conformality is more than 80%.

The method of any one of paragraphs [0008]-[00020] or any combinations of two or more of paragraphs [0008]-[00020], further comprising a step of heating or cooling the carbon containing molecule in a container to thereby control a partial vapor pressure of the carbon containing molecule in the container.
The method of any one of paragraphs [0008]-[00021] or any combinations of two or more of paragraphs [0008]-[00021], further comprising a step of heating the substrate to a temperature of at least 50° C.
The method of paragraph [0022] wherein the temperature is between 100 and 700° C.
The method of any one of paragraphs [0008]-[00023] or any combinations of two or more of paragraphs [0008]-[00023], wherein the deposition step is performed at a pressure lower than 750 Torr.
The method of any one of paragraphs [0008]-[00024] or any combinations of two or more of paragraphs [0008]-[00024], wherein the deposition step is performed at a pressure between 0.1 and 250 Torr.
The method of any one of paragraphs [0008]-[00025] or any combinations of two or more of paragraphs [0008]-[00025], further comprising a step of supplying one or more of styrene, toluene, xylene, pyridine, acetophenone, or phenol to the deposition step.

The compounds listed in table one have suitable properties for amorphous carbon deposition. Having low hydrogen content makes possible an effective tuning of the carbon to hydrogen ratio in the film. For example, pure hydrogen gas can be used in the process to increase the amount of H in the film, as needed. In one preferred embodiment, a carbon to hydrogen ratio greater than 0.7 enables low Hydrogen content amorphous carbon film deposition. In another preferred embodiment, the carbon to hydrogen ratio is greater than 1.

In another embodiment, C₆F₆ may be used for co-deposition of both Carbon and Fluorine.

The compounds of table one have suitable physical properties for easy installation and use in semiconductor manufacturing. While not always gases at room temperature, the compounds have a sufficient vapor pressure to make feasible delivery into a chamber with or without a carrier gas.

In another embodiment, the vapors of the chemicals in table one are reacted in a plasma to form new plasma reaction products such as larger molecules or molecular clusters. The plasma reaction products may enhance the amorphous carbon deposition process. Cyclic molecules are preferred when the deposition rate should be higher than is typical for the genus of molecules.

TABLE 1
Example of high C content molecules useful for a-C deposition.

| | | Melting | Boiling | Vapor | |
|---|---|---|---|---|---|
| | | point | Point | Pressure | [C/H] |
| Name | Formula | (C.) | (C.) | (Torr) | ratio |
| 1,2,3,4,5,6- | C₆F₆ | 4 | 81 | 95 | Ø |
| hexafluorobenzene | | | | (25 C.) | |
| Diphenylacetylene | C₁₄H₁₀ | 62.5 | 300 | 20 | 1.4 |
| | | | | (170 C.) | |
| Naphtalene | C₁₀H₈ | 80 | 218 | 1 | 1.25 |
| | | | | (53 C.) | |
| Azulene | C₁₀H₈ | 100 | 242 | 0.0091 | 1.25 |
| | | | | (25 C.) | |
| Cyclooctatetraene | C₈H₈ | −5 | 142 | 7.9 | 1 |
| | | | | (25 C.) | |
| Benzene | C₆H₆ | 5.5 | 80 | 100 | 1 |
| | | | | (26 C.) | |
| Acetylene | H—C≡C—H | NA | −84 | 33400 | 1 |
| | | | | (20 C.) | |
| BCHD | C₇H₈ | −19 | 89 | 50 | 0.88 |
| | | | | (20 C.) | |
| Cycloheptatriene | C₇H₈ | −80 | 116 | 18 | 0.88 |
| | | | | (20 C.) | |
| Cyclopentadiene | C₅H₆ | −85 | 41 | 400 | 0.83 |
| | | | | (20 C.) | |
| Cyclohexadiene | C₆H₈ | −49 | 88 | 77 | 0.75 |
| | | | | (25 C.) | |
| Pentadiene | C₅H₈ | −87 | 42 | 620 | 0.63 |
| | | | | (37 C.) | |
| Hexadiene | C₆H₁₀ | −141 | 60 | 367 | 0.6 |
| | | | | (37 C.) | |
| Diethynylbenzene | C₁₀H₆ | Solid | 188 C. | 14 | 1.67 |
| | 1785-61-1 | | | (78 C.) | |
| Phenylacetylene | C₈H₆ | −45 C. | 142 C. | 7 | 1.3 |
| | 536-74-3 | | | (25 C.) | |
| Phenyl propyne | C₉H₈ | Liquid | 183 | 1.2 | 1.125 |
| | 673-32-5 | <20 C. | | (25 C.) | |
| Phenyl propyne | C₉H₈ | Liquid | NA | 20 | 1.125 |
| | 10147-11-2 | <20 C. | | (75 C.) | |
| Ethynyltoluene | C₉H₈ | Liquid | 168 C. | NA | 1.125 |
| | 766-97-2 | <20 C. | | | |
| Hexadiyne | C₆H₆ | 68 | 128 C | ~12 | 1 |
| | 2809-69-0 | | | (25 C.) | |
| Phenyl butyne | C₁₀H₁₀ | Liquid | 190 C. | NA | 1 |
| | 16520-62-0 | <20 C. | | | |
| 2,5-Heptadiyne | C₇H₈ | NA | 140 C. | 7 | 0.88 |
| | 50428-63-2 | | (est.) | (25 C.) | |
| | | | | (est.) | |
| (tButyl)phenylacetylene | C₁₂H₁₄ | Liquid | NA | 2 | 0.857 |
| | 772-38-3 | | | (70 C.) | |
| Methylbutenyne | C₅H₆ | −113 | 32 | 750 | 0.83 |
| | 78-80-8 | | | (30 C.) | |
| Cyclopropyl acetylene | C₅H₆ | Liquid | 52-65 C. | NA | 0.83 |
| | 6746-94-7 | | | | |
| Ethynylcyclohexene | C₈H₁₀ | Liquid | ~150 | ~5 | 0.8 |
| | 931-49-7 | <20 C. | | (25 C.) | |
| cyclopentylacetylene | C₇H₁₀ | Liquid | 105 | NA | 0.7 |
| | 930-51-8 | <20 C. | | | |
| Cyclohexylacetylene | C₈H₁₂ | Liquid | 130 | NA | 0.67 |
| | 931-48-6 | <20 C. | | | |
| Methylbutyne | C₆H₁₀ | −78 | 37 | 410 | 0.6 |
| | 917-92-0 | | | (20 C.) | |

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method of depositing amorphous carbon on a substrate using at least one carbon containing molecule having at least one carbon atom the method comprising the steps of supplying the carbon containing molecule and carrying out the deposition to thereby form a deposited amorphous carbon on the substrate, wherein a carbon to hydrogen ratio of the molecule is equal to or more than 0.7.

2. The method of claim 1, wherein the carbon to hydrogen ratio of the carbon containing molecule is equal to or more than 1.

3. The method of claim 1, wherein the carbon containing molecule is represented by the general formula CxHy with x and y being an integer >0.

4. The method of claim 3, wherein x/y ratio is >0.7.

5. The method of claim 3, wherein the ratio x/y≧1.

6. The method of claim 1, wherein the amorphous carbon deposition step comprises chemical vapor deposition (CVD), plasma enhanced-CVD (PECVD), pulsed-CVD, pulsed-PECVD, atomic layer deposition (ALD), plasma enhanced ALD (PEALD), cat-CVD, sub atmospheric CVD (SACVD), or a derivate method.

7. The method of claim 1, wherein the method further comprises a step of co-implanting the amorphous carbon with other elements.

8. The method of claim 1, wherein the carbon containing molecule is one or more of: C₆F₆, diphenylacetylene, naphthalene, azulene, cyclooctatetraene, Norbadiene, cycloheptatriene, cyclohexadiene, cyclopentadiene, diethynylbenzene, phenylacetylene, phenylpropyne, ethynyltoluene, hexadiyne, phenyl butyne, 1,5-hetadiyne, (tButyl)phenylacetylene, methylbutenyne, cyclopropylacetylene, ethynylcyclohexene, cyclopentylacetylene, or methylbutyne.

9. The method of claim 1, wherein the deposition step comprises is a plasma induced reaction that yields reaction products of the carbon containing molecule.

10. The method of claim 1, wherein the deposition step comprises a step of supplying an inert or a reactive gas in addition to the carbon containing molecule.

11. The method of claim 10, wherein the inert or reactive gas is one or more of N₂, H₂, NH₃, O₂, CO₂, CO, benzene, CH₄, pentadiene, hexadiene, cyclohexylacetylene, C₂H₂, or C₂1H₄.

12. The method of claim 1, wherein the deposited amorphous carbon is deposited on patterned structures with a conformality of at least 50%

13. The method of claim 12, wherein the conformality is more than 80%.

14. The method of claim 1, further comprising a step of heating or cooling the carbon containing molecule in a container to thereby control a partial vapor pressure of the carbon containing molecule in the container.

15. The method of claim 1, further comprising a step of heating the substrate to a temperature of at least 50° C.

16. The method of claim 15, wherein the temperature is between 100 and 700° C.

17. The method of claim 1, wherein the deposition step is performed at a pressure lower than 750 Torr.

18. The method of claim 17, wherein the deposition step is performed at a pressure between 0.1 and 250 Torr.

19. The method of claim 1, further comprising a step of supplying one or more of styrene, toluene, xylene, pyridine, acetophenone, or phenol to the deposition step.
